(19) United States
(12) Patent Application Publication
(10) Pub. No.: US 2006/0091504 A1
(43) Pub. Date: May 4, 2006

(54) Film circuit substrate having Sn-In alloy layer

(76) Inventors: Un-Byoung Kang, Gyeonggi-do (KR); Chung-Sun Lee, Gyeonggi-do (KR); Sa-Yoon Kang, Seoul (KR); Yong-Hwan Kwon, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/256,650

(22) Filed: Oct. 21, 2005

(30) Foreign Application Priority Data
Oct. 21, 2004 (KR) 2004-84517

(51) Int. Cl. H01L 23/58

(52) U.S. Cl. 257/643

(57) ABSTRACT

In one embodiment, a film circuit substrate comprises an insulating film made of polyimide resin; a conductive circuit pattern formed on the insulating film, the circuit pattern including an inner lead to be connected with a conductive bump of a semiconductor chip through a bump bonding process; and a tin-indium alloy layer formed on the inner lead to produce an inter-metallic compound layer of AuₓSn composition during the bump bonding process.

### CROSS REFERENCE TO RELATED APPLICATIONS

This U.S. non-provisional application claims benefit of priority under 35 U.S.C. §119 of Korean Patent Application No. 2004-84517, filed on Oct. 21, 2004, the entire contents of which are incorporated herein by reference.

### BACKGROUND OF THE INVENTION

1. Field of the Invention

The present invention relates to a film circuit substrate, more specifically, to a film circuit substrate that enables connection of inner leads with gold bumps of a semiconductor chip through inner-lead bonding at a lower temperature.

2. Description of the Related Art

Corresponding to rapid technical advances in semiconductor devices toward higher integration and thinness, there have been great advances in assembly technologies for manufacturing semiconductor packages. As portable electronic equipment becomes smaller in size and lighter in weight, its market demand has rapidly expanded worldwide. In liquid crystal display (LCD) panel markets, the demand for driver integrated circuit chips to support colors and moving pictures has caused an explosive increase in the number of chip pads.

Accordingly, there has been an increasing demand for a semiconductor package utilizing a film circuit substrate, such as a COF (Chip On Film) package or a TCP (Tape Carrier Package), which has advantages in achieving fine pitch, miniaturization, and thinness.

Hereinafter, a conventional film circuit substrate and a structure of a semiconductor chip package utilizing the conventional film circuit substrate are explained.

FIG. 1 is a schematic top view showing a semiconductor chip mounted on the conventional film circuit substrate. FIG. 2 is an enlarged sectional view showing a circuit pattern of the conventional film circuit substrate.

Referring to FIGS. 1 and 2, the film circuit substrate 300 in the prior art is a flexible circuit substrate utilized for manufacturing a chip on film package. The film circuit substrate 300 has a conductive circuit pattern 303 formed on an insulating film 301 made of polyimide. The conductive circuit pattern 303 constitutes a designated circuit by using a metal with superior electrical conductivity such as copper (Cu). The conductive circuit pattern 303 is covered with and protected by a protective film such as a solder resist coating.

In the central area of the film circuit substrate 300, there exists a portion, referred to as an inner lead 305 (indicated, but not visible in FIG. 1 because it is covered by semiconductor chip 21), which extends from the conductive circuit pattern 303 covered with the protective film and which is exposed from the protective film to mount the semiconductor chip 21. On the border of the film circuit substrate 300, there exists a portion, referred to as an outer lead 307, which is extended from the conductive circuit pattern 303 and is exposed from the protective film for external connection. As shown in FIG. 2, the inner lead 305 is covered with a tin (Sn) plated layer 311 so that the semiconductor chip 21 can be mounted without any flux.

The film circuit substrate 300 is manufactured by: forming a copper metal layer on the insulating film 301 made of polyimide through electrolytic plating; forming a designated conductive circuit pattern 303 through exposure; and forming a tin plated layer 311 on the conductive circuit pattern 303 through electroless plating. The thickness of the tin plated layer 311 is commonly less than or equal to 1 μm.

FIG. 3 is a partial sectional view showing a chip on film package utilizing the conventional film circuit substrate. FIG. 4 is a sectional view showing a step of inner lead bonding in a manufacturing process for a chip on film package utilizing the conventional film circuit substrate.

The semiconductor chip package 50, shown in FIG. 3, is a chip on film package that is mainly used to drive a display device, and has a semiconductor chip 21 mounted on the film circuit substrate 300.

The semiconductor chip 21 is mounted by connecting a gold bump 23 formed thereon with the inner lead 305 of the film circuit substrate 300. The chip mounting and electrical interconnections are performed through inner lead bonding (ILB), whereby melting and bonding can be performed at a high temperature above 380° C. without any flux since the inner lead 305 is covered with the tin plated layer 311.

The chip mounting process is explained in detail with reference to FIG. 4. The film circuit substrate 306 is loaded on a bonding stage 501 maintaining a temperature in the range of 100 to 120° C. Next, the semiconductor chip 21 is aligned and then mounted on the film circuit substrate 300 by a bonding tool 503 heated at a temperature in the range of 400 to 500° C. Melting the tin plated layer 311 formed on the inner lead 305 at a temperature above 380° C. results in connections in a lump between the gold bumps 23 and the inner leads 305. Consequently, the semiconductor chip 21 and the film circuit substrate 300 are electrically interconnected.

However, a serious shrinkage phenomenon may occur in the conventional film circuit substrate during the chip mounting process. The film circuit substrate is heated over 380° C. owing to the heat transferred from the bonding tool, and then rapidly cooled down to room temperature after the chip mount. In particular, the coefficient of thermal expansion of silicon which is the main constituent of the semiconductor chip is 2.7×10⁻⁶/° C., and that of polyimide which is the main constituent of the insulating film of the film circuit substrate is 1.7×10⁻⁵/° C. As a result, the insulating film shrinks more than the semiconductor chip does after the inner lead bonding.

Such shrinkage of the insulating film due to temperature change may causes misalignment between the semiconductor chip and the film circuit substrate, a loose connection of the gold bump, and damage to the leads. Consequently, this lowers the quality of the chip mounting and electrical connection, and thereby results in a low-quality semiconductor chip package. Such a problem becomes more serious in a fine pitch tape carrier package or chip on film package having multiple channels, which is required for a high-definition and high-quality liquid crystal display product. The decreasing size of bumps, corresponding to a trend toward finer pitch circuit patterns, makes the problem worse.

FIG. 5 is a picture, taken by an electron microscope, showing loose connection phenomena of gold bumps in the COF package of FIG. 3. Referring to FIG. 5, it can be understood that a loose connection of the gold bump occurs in reality owing to the shrinkage of the insulating film. The loose connection of the gold bump may cause intermittent transmission of electric signals, and thereby lower operational reliability of the semiconductor package. In addition, there may occur a physical problem such as a crack resulting from moisture absorbed in a space created by the loose connection.

Accordingly, the object of the present invention is to provide a film circuit substrate that makes it possible to mount a semiconductor chip at a lower temperature, and thereby to prevent defects such as loose connections of gold bumps caused by the shrinkage due to a difference in thermal expansion between a semiconductor chip and a film circuit substrate.

### SUMMARY

In one embodiment, a film circuit substrate comprises an insulating film made of polyimide resin; a conductive circuit pattern formed on the insulating film, the circuit pattern including an inner lead to be connected with a conductive bump of a semiconductor chip through a bump bonding process; and a tin-indium alloy layer formed on the inner lead to produce an inter-metallic compound layer of AuₓSn composition during the bump bonding process. With this embodiment, the shrinkage of the insulating film can be significantly reduced. Consequently, defects in alignment between the semiconductor chip and the film circuit substrate can be reduced; and loose connections or delamination of conductive bumps such as gold bumps and lead damage can be prevented.

### BRIEF DESCRIPTION OF THE DRAWINGS

FIG. 1 is a schematic top view showing a semiconductor chip mounted on a conventional film circuit substrate.

FIG. 2 is an enlarged sectional view showing a circuit pattern of the conventional film circuit substrate.

FIG. 3 is a partial sectional view showing a chip on film package utilizing the conventional film circuit substrate.

FIG. 4 is a sectional view showing a step of inner lead bonding in a manufacturing process for a chip on film package utilizing the conventional film circuit substrate.

FIG. 5 is a picture, taken by an electron microscope, showing loose connection phenomena of gold bumps in the chip on film package of FIG. 3.

FIGS. 6 and 7 are partial sectional views showing a film circuit substrate according to some embodiments of the present invention.

FIG. 8 is an enlarged sectional view showing a circuit pattern of the film circuit substrate according to some embodiments of the present invention.

FIG. 9 is a composition ratio (horizontal axis) v. temperature (vertical axis) graph showing melting points for the tin-indium alloy that is utilized for the film circuit substrate according to some embodiments of the present invention.

FIG. 10 is a partial sectional view showing a semiconductor chip mounted on the film circuit substrate according to some embodiments of the present invention.

FIG. 11 is a partial sectional view showing a step of inner lead bonding in a manufacturing process for a chip on film package utilizing the film circuit substrate according to the present invention.

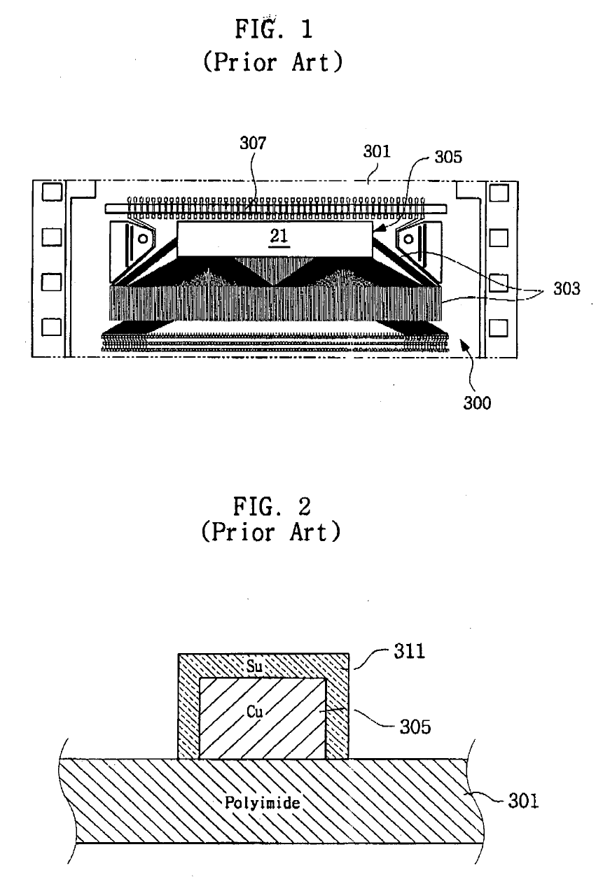

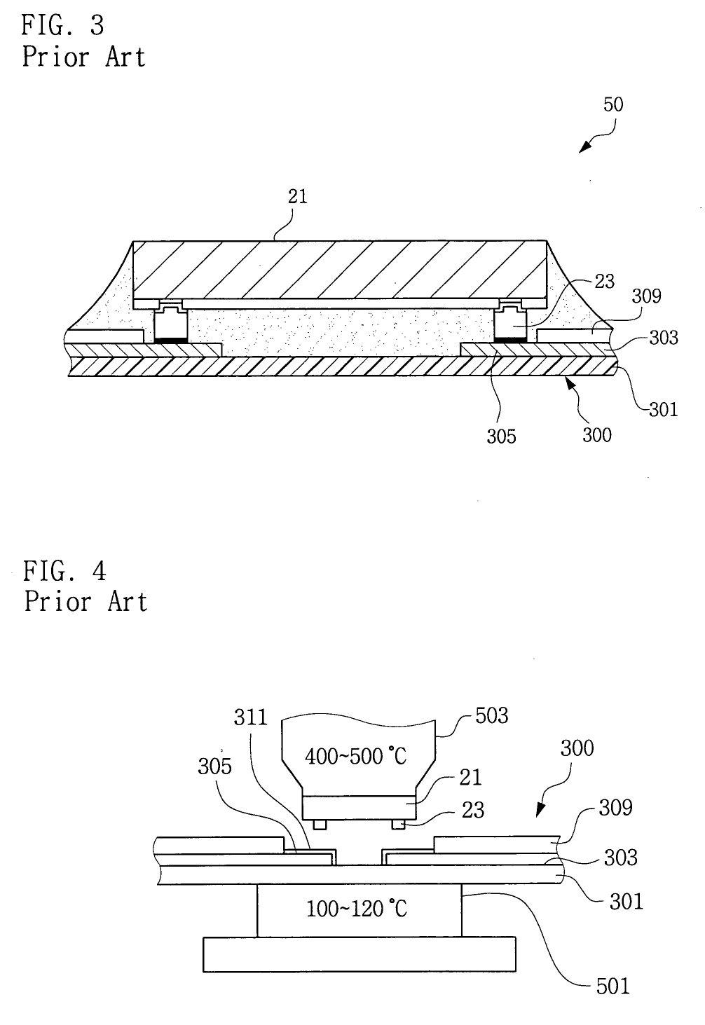

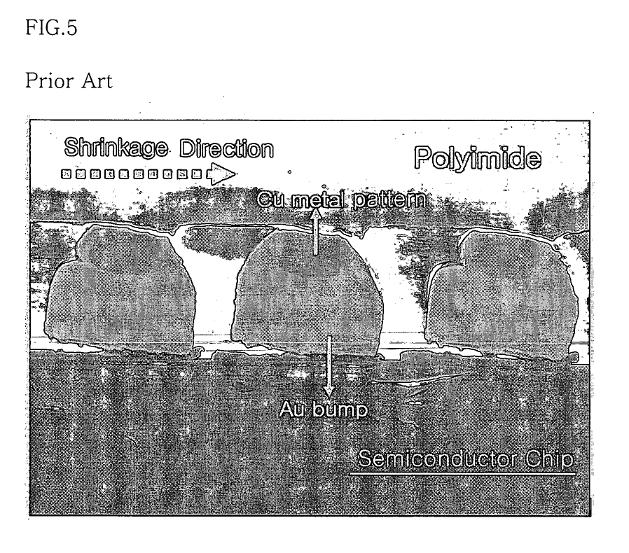

### DETAILED DESCRIPTION

Hereinafter, film circuit substrates according to exemplary embodiments of the present invention will now be described in detail with reference to the accompanying drawings. It should be noted that in the following explanation only matters relevant to the understanding of the present invention are explained to avoid obscuring the gist of the present invention. In the same manner, in the accompanying drawings some elements are exaggerated, omitted, or just outlined in brief, and may be not drawn to scale.

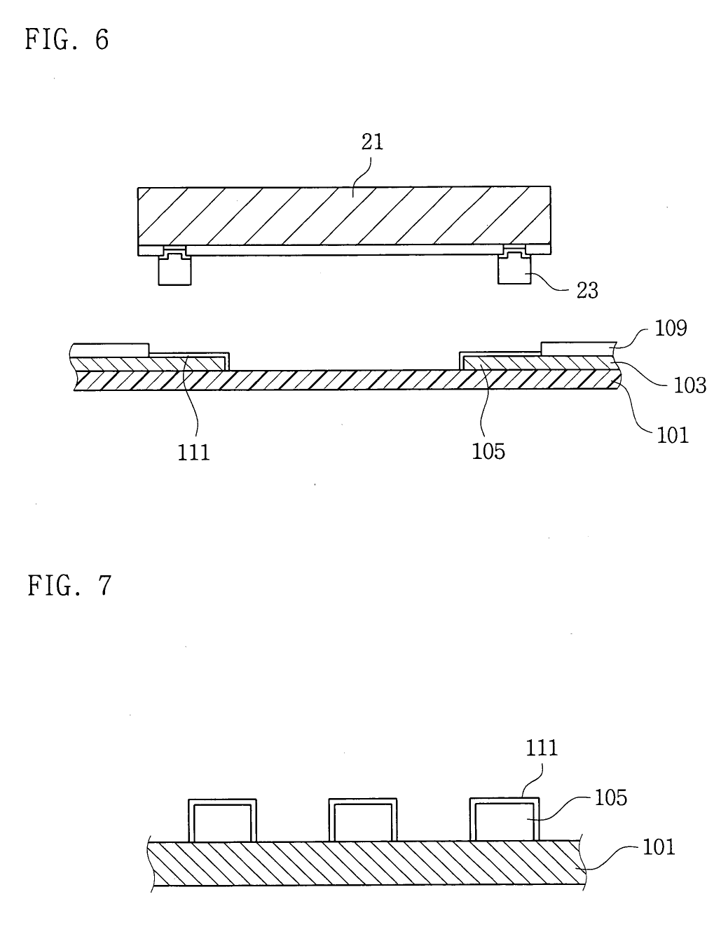

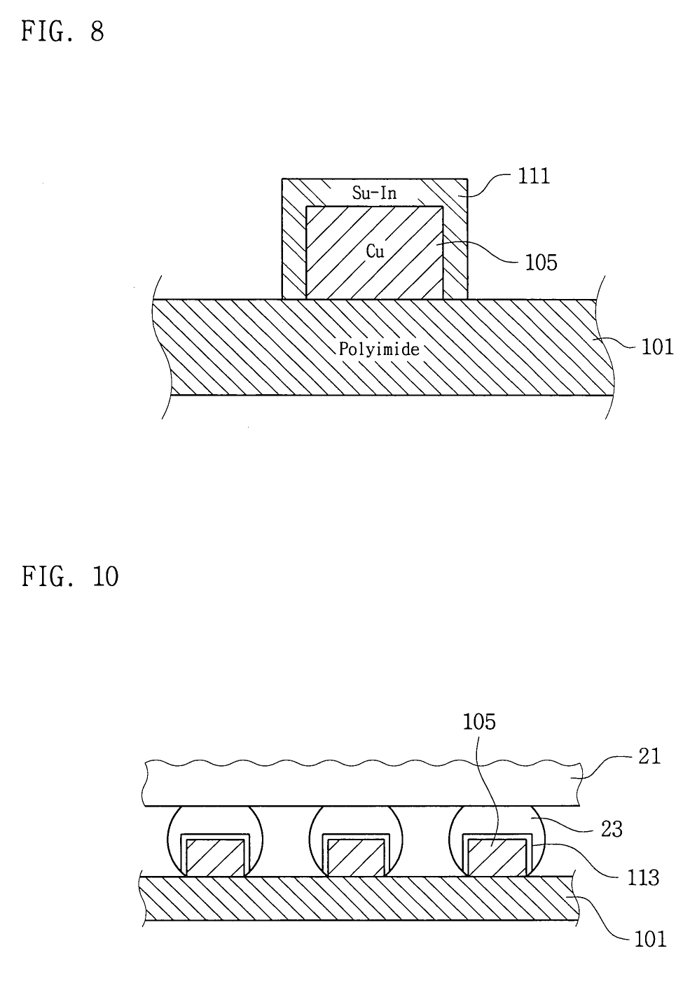

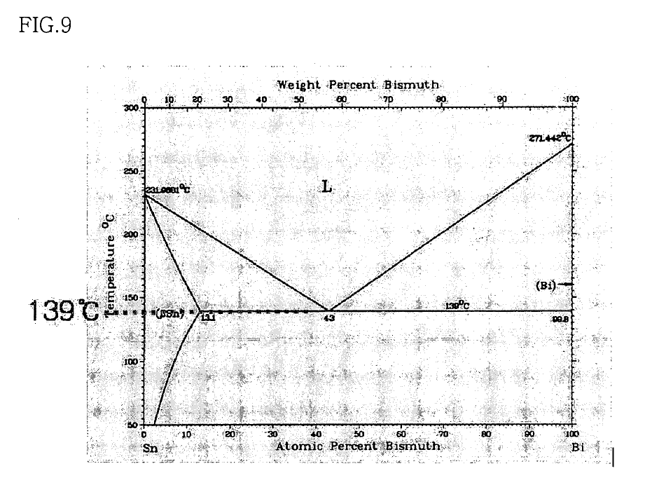

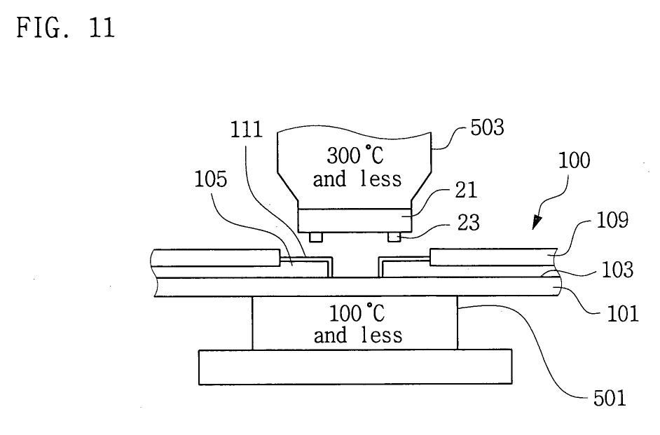

FIGS. 6 and 7 are partial sectional views showing a film circuit substrate according to the present invention. FIG. 8 is an enlarged sectional view showing a circuit pattern of the film circuit substrate according to the present invention. FIG. 9 is a composition ratio (horizontal axis) v. temperature (vertical axis) graph showing melting points of the tin-indium alloy that is utilized for the film circuit substrate according to the present invention. FIG. 10 is a partial sectional view showing a semiconductor chip mounted on the film circuit substrate according to the present invention. FIG. 11 is a partial sectional view showing a step of inner lead bonding in a manufacturing process for a chip on film package utilizing the film circuit substrate according to the present invention.

Referring to FIGS. 6 to 8, the film circuit substrate 100 according to the present invention is utilized for a chip on film package, in which a semiconductor chip 21 having a gold bump 23 is mounted by bump bonding. The film circuit substrate 100 comprises: an insulating film 101 made of polyimide resin, a conductive circuit pattern 103 formed on the insulating film 101, an inner lead 105 contained in the conductive circuit pattern 103, and a tin-indium (Sn—In) alloy layer 111 formed on the inner lead 105. The conductive circuit pattern 103 is formed so that the copper inner lead 105 is placed in the central region of the insulating film 101.

The tin-indium alloy layer 111 lowers the melting temperature required to connect the inner lead 105 and the gold bump 23. It is preferable that the tin-indium alloy layer 111 has a 48 wt % Sn:52 wt % In composition ratio. As can be understood from the graph in FIG. 9, the tin-indium alloy layer 111 having the 48 wt % Sn:52 wt % In composition ratio has a melting point of about 117° C. Moreover, a useful composition ratio range for Sn to In by weight is from about 45 wt % Sn:55 wt % In to about 55 wt % Sn:45 wt % In. Consequently, the inner lead bonding can be performed at a temperature lower than that of common soldering. The melting point of the tin-indium alloy layer 111 is lower by about 115° C. than the 232° C. melting point of pure tin.

The tin-indium alloy layer 111 is to form an AuₓSn layer as an inter-metallic compound layer 113 during bonding. It is preferable that the inter-metallic compound layer 113 is composed of an alloy of 80 wt % gold and 20 wt % tin-indium. The inter-metallic compound layer 113 is created by randomly mixing Au₅Sn and AuSn during bonding. It is more preferable that the inter-metallic compound layer 113 is formed to have a composition of gold and tin at an average atomic ratio of 4:1. In addition, the indium constituent of the tin-indium alloy layer 111 has good reactivity to gold or copper, and thereby enhances bonding strength.

It is known that a tin-bismuth (Sn—Bi) alloy can also lower the melting point required for the bump bonding. The tin-bismuth alloy forms an AuSn₂ layer as an inter-metallic compound layer. However, the AuSn₂ inter-metallic compound is very weak under mechanical stress and has poor reactivity to gold or copper. Hence, upon bump bonding, a bismuth layer formed between the gold bump and the copper circuit pattern is weak under mechanical stress, and it is difficult to achieve bonding reliability. Furthermore, the tin-bismuth alloy has a minimum melting point of 139° C., which is higher than that of the tin-indium alloy 111 of the film circuit substrate 100 according to the present invention.

The conductive circuit pattern 103 is covered with and protected by a protective film 109. The inner lead 105 exposed from the protective film 109 can be formed to have a thickness of 8 to 12 μm. The tin-indium alloy layer 111 can be formed to have a thickness of 0.1 μm to 1 μm. It is preferable that the tin-indium alloy layer 111 has a thickness of 0.5 μm, though its thickness may vary if necessary. The gold bump 23 to be connected with the inner lead 105 may have a thickness of 14 to 17 μm.

The tin-indium alloy layer 111 can be formed by various plating methods such as an electrolytic, electroless or immersion plating.

The chip mounting process is explained in detail with reference to FIG. 11. The film circuit substrate 100 is loaded on a bonding stage 501 maintaining a temperature less than or equal to 100° C. Next, the semiconductor chip 21 is aligned and then mounted on the film circuit substrate 100 by a bonding tool 503 heated to a temperature less than or equal to 300° C. Since the melting point of the tin-indium alloy layer 111 is low, the bonding stage 501 and the bonding tool 503 are heated at temperatures of less than or equal to 100° C. and 300° C. respectively, though their temperatures may vary depending on kinds or specifications of the film circuit substrate 100. Melting the tin-indium alloy layer 111 formed on the inner lead 105 at a temperature less than or equal to 200° C. results in connections in a lump between the gold bumps 23 and the inner leads 105. Consequently, the semiconductor chip 21 and the film circuit substrate 100 are electrically interconnected. In this bonding process, since the required temperature is low, the impact of thermal stress is reduced; and the bonding strength is enhanced because not only tin but also indium reacts well with the gold bump or copper circuit pattern.

As described before, the film circuit substrate in accordance with the present invention forms the tin-indium alloy layer on the conductive circuit pattern, so the melting point required in the inner lead bonding is lowered by more than 100° C. compared with the case of a tin plated layer. Consequently, the temperatures of both the bonding stage and the bonding tool can be significantly lowered. In particular, the inner lead bonding can be performed with the bonding tool having a temperature of less than or equal to 300° C. The heat transferred to the film circuit substrate, which is greatly and adversely affected by thermal stress due to its thinness, is significantly reduced; and also the thermal stress in the inner lead bonding is reduced, and the amount of its shrinkage and expansion decreases.

The inner lead formed in the conductive circuit pattern is formed to have a thickness of less than or equal to 10 μm. The inner lead plays a role in enhancing the bonding strength by forming an AuIn inter-metallic compound layer due to high reactivity between indium and gold in addition to an AuₓSn inter-metallic compound layer of 3 to 4 μm thickness. Furthermore, since the thickness of the tin-indium alloy layer is less than or equal to 1 μm, the amount of expensive indium required can be minimized.

Accordingly, the film circuit substrate having a tin-indium alloy layer according to the present invention makes it possible to connect the gold bump formed on a semiconductor chip with the inner lead formed on the polyimide insulating film at a lower temperature, and thereby to reduce the shrinkage of the insulating film. Consequently, defects in alignment between the semiconductor chip and the film circuit substrate can be reduced; and the amount of shrinkage and expansion of the insulating film can also be reduced. This reduced amount of shrinkage and expansion can prevent loose connections or delamination of gold bumps, and can also reduce damage to the leads. In addition, the low-temperature film circuit substrate according to the present invention can be effectively utilized for manufacturing a chip on film (COP) package or a tape carrier package (TCP) for display devices.

Reference throughout this specification to “some embodiments,” “one embodiment” or “an embodiment” means that a particular feature, structure, or characteristic described in connection with the embodiment is included in at least one embodiment of the present invention. Thus, the appearances of these phrases in various places throughout this specification are not necessarily all referring to the same embodiment. Furthermore, the particular features, structures, or characteristics may be combined in any suitable manner in one or more embodiments.

The present invention has been disclosed by the preferred embodiments shown in this specification and accompanying drawings using specific terms. This disclosure is not to limit the scope of the invention, but to serve only for illustrative purposes. It should be understood to the ordinary person skilled in the art that various changes or modifications of the embodiments are possible without departing from the spirit of the invention.

What is claimed is:

1. A film circuit substrate comprising:
an insulating film made of polyimide resin;
a conductive circuit pattern formed on the insulating film, the circuit pattern including an inner lead to be connected with a conductive bump of a semiconductor chip through a bump bonding process; and
a tin-indium alloy layer formed on the inner lead to produce an inter-metallic compound layer of AuₓSn composition during the bump bonding process.

2. The film circuit substrate according to claim 1, wherein the tin-indium alloy layer has a composition of tin:indium at a weight percent ratio of about 48:52.

3. The film circuit substrate according to claim 1, wherein the tin-indium alloy layer has a thickness of about 0.1 to about 1 μm.

4. The film circuit substrate according to claim 1, wherein the tin-indium alloy layer forms the inter-metallic compound layer composed of an alloy of about 80 wt % gold and about 20 wt % tin-indium.

5. The film circuit substrate according to claim 1, wherein the tin-indium alloy layer forms the inter-metallic compound layer having a composition of gold and tin at an average atomic ratio of about 4:1.

6. The film circuit substrate according to claim 1, wherein the conductive circuit pattern is formed of a material including copper.

7. The film circuit substrate as claimed in any of claims 1, wherein the film circuit substrate is utilized in a chip on film (COF) package, wherein the inner lead is formed in the central region of the film circuit substrate, and wherein the conductive circuit pattern connected to the inner lead is configured in a radial shape.

8. The film circuit substrate as claimed in any of claims 1, wherein the film circuit substrate is utilized in a tape carrier package (TCP), wherein a window penetrating the insulating film is formed in the central region of the film circuit substrate, and wherein the inner lead is configured project into the window.

9. A method of fabricating a film circuit substrate, the method comprising:
preparing an insulating film;
forming on the insulating film a conductive circuit pattern that includes an inner lead to be connected with a conductive bump of a semiconductor chip; and
forming on the inner lead a tin-indium alloy layer.

10. The method of claim 9, which further comprises:
mounting a semiconductor chip having the conductive bump on the insulating film over the conductive circuit to align the conductive bump with the inner lead; and
bump bonding the semiconductor chip to the conductive circuit pattern including the inner lead.

11. The method of claim 10, wherein the bump bonding produces an inter-metallic compound layer of an AuₓSn composition.

12. The method of claim 10, wherein the bump bonding of the semiconductor chip to the conductive circuit pattern including the inner lead is performed at a temperature of less than about 200 degrees centigrade.

13. The method of claim 9 which, before the alloy-layer forming, further comprises:
preparing a tin-indium alloy having a composition of tin:indium at a weight percent ratio of between about 45:55 and about 55:45.

14. The method of claim 13, wherein the composition of tin:indium is at a weight percent ratio of about 48:52.
